(19) United States
(12) Patent Application Publication
(10) Pub. No.: US 2024/0072534 A1
(43) Pub. Date: Feb. 29, 2024

(54) START METHOD FOR PHOTOVOLTAIC RAPID SHUTDOWN SYSTEM, APPLICATION APPARATUS AND SYSTEM

(71) Applicant: Sungrow Power Supply Co., Ltd., Hefei (CN)

(72) Inventors: Yu Yang, Hefei (CN); Yanfei Yu, Hefei (CN); Jun Xu, Hefei (CN); Qiaodi Chen, Hefei (CN)

(73) Assignee: Sungrow Power Supply Co., Ltd., Hefei (CN)

(21) Appl. No.: 18/271,842

(22) PCT Filed: Jan. 10, 2022
(86) PCT No.: PCT/CN2022/070931

§ 371 Date: Jul. 11, 2023

(30) Foreign Application Priority Data
Jan. 15, 2021 (CN) 202110054675.4

(51) Int. Cl. H02H 7/20; H02H 1/00; H02S 50/10

(52) U.S. Cl. CPC H02H 7/20; H02H 1/0007; H02S 50/10

(57) ABSTRACT

A start method for a photovoltaic rapid shutdown system, an application apparatus and a system. In the method, an inverter system controls the voltage change of a corresponding direct current bus in a photovoltaic rapid shutdown system; and a photovoltaic module shutdown device performs determination according to a measured output voltage of itself, and controls itself to be turned on when the change characteristic of the voltage of the direct current bus connected to itself satisfies a preset turn-on condition. Therefore, merely by means of a self-contained voltage sampling device, the photovoltaic module shutdown device can determine whether a turn-on signal is received, without additionally providing a corresponding receiving device, thereby reducing hardware cost of the photovoltaic module shutdown device while realizing communication between the photovoltaic module shutdown device and the outside.

This application claims the priority to Chinese Patent Application No. 202110054675.4 titled “METHOD FOR STARTING RAPID SHUTDOWN SYSTEM, DEVICE AND SYSTEM APPLYING THE SAME”, filed on Jan. 15, 2021 with the China National Intellectual Property Administration, which is incorporated herein by reference in its entirety.

### FIELD

The present disclosure relates to the technical field of grid-connected photovoltaic systems, and in particular to a method for starting a rapid shutdown system, a device applying the method and a system applying the method.

### BACKGROUND

In the field of generating electric power from renewable energy, generation of electric power from solar energy is widely applied. Direct-current power outputted from a photovoltaic array in a photovoltaic system is converted into alternating-current power by an inverter, and then is delivered to an electrical grid. The photovoltaic array outputs high-voltage power, and thus is necessarily rapidly de-energized in case of failure, in order to secure the photovoltaic system from hazards. Further, the photovoltaic system is desired to resume generating electric power as soon as the fault is repaired. That is, a rapid shutdown device connected to a photovoltaic module in the photovoltaic system is turned on immediately after the fault is repaired, so that the electric power outputted by the photovoltaic module can be outputted to the electrical grid.

In the conventional technology, a central controller constantly transmits a heartbeat signal so as to turn on the rapid shutdown device. Alternatively, a shutdown control module arranged on a direct-current bus transmits an excitation pulse periodically so as to turn on the rapid shutdown device. In these two solutions, an additional receiving module is essential for the rapid shutdown device, resulting in high cost of the rapid shutdown device in terms of hardware.

### SUMMARY

A method for starting a rapid shutdown system, a device applying the method and a system applying the method are provided according to the present disclosure, to reduce costs of the rapid shutdown device in the rapid shutdown system and even the rapid shutdown system in terms of hardware while starting the rapid shutdown system timely.

In a first aspect, a method for starting a rapid shutdown system is provided according to the present disclosure. The method includes: regulating, by an inverter system in the rapid shutdown system, a voltage across a direct-current bus in the rapid shutdown system; determining, by a rapid shutdown device connected to the direct-current bus in the rapid shutdown system based on a detected voltage outputted by the rapid shutdown device, whether a change in the voltage across the direct-current bus meets a preset conduction condition; and switching the rapid shutdown device on in response to a determination result that the change in the voltage across the direct-current bus already meets the preset conduction condition.

In an embodiment, the preset conduction condition is that the voltage across the direct-current bus includes a small pulse.

In an embodiment, the small pulse is formed by short-circuiting the direct-current bus and stopping short-circuiting the direct-current bus.

In an embodiment, the small pulse is formed by alternately short-circuiting the direct-current bus and stopping short-circuiting the direct-current bus.

In an embodiment, the method further includes: keeping the rapid shutdown device off in response to a determination result that the change in the voltage across the direct-current bus does not meet the preset conduction condition, after the determining, by the rapid shutdown device in the rapid shutdown system connected to the direct-current bus based on a detected voltage outputted by the rapid shutdown device, whether the change in the voltage across the direct-current bus meets the preset conduction condition.

In an embodiment, the method further includes: before the regulating, by the inverter system in the rapid shutdown system, the voltage across the direct-current bus in the rapid shutdown system, determining, by the rapid shutdown device, whether a detected state parameter of the rapid shutdown device meets a preset normal condition; outputting, by the rapid shutdown device, a preset starting voltage to the direct-current bus connected to the rapid shutdown device, in a case that that the state parameter already meets the preset normal condition; and detecting, by the inverter system, the voltage across the direct-current bus, and determining, by the inverter system, whether the detected voltage across the direct-current bus meets a starting condition, where the voltage across the direct-current bus is regulated by the inverter system in a case that the detected voltage across the direct-current bus meets the starting condition.

In an embodiment, the state parameter includes at least one of an input current, an input voltage, and a temperature.

In an embodiment, the detecting, by the inverter system, the voltage across the direct-current bus, and determining, by the inverter system, whether the detected voltage across the direct-current bus meets the starting condition includes: detecting, by the inverter system, the voltage across the direct-current bus; determining, by the inverter system based on the detected voltage across the direct-current bus, the number of the rapid shutdown device that has outputted the starting voltage to the direct-current bus; determining, by the inverter system, whether the number of the rapid shutdown device that has outputted the starting voltage is greater than or equal to a preset number; determining that the voltage across the direct-current bus already meets the starting condition, in a case that the number of the rapid shutdown device that has outputted the starting voltage is greater than or equal to the preset number; and determining that the voltage across the direct-current bus does not meet the starting condition in a case that the number of the rapid shutdown device that has outputted the starting voltage is less than the preset number.

In an embodiment, the regulating, by the inverter system in the rapid shutdown system, the voltage across the direct-current bus in the rapid shutdown system includes: regulating, by the inverter system, the voltage across the direct-current bus in a preset manner, so that the voltage across the direct-current bus changes in a preset pattern.

In an embodiment, the regulating, by the inverter system, the voltage across the direct-current bus in the preset manner includes: short-circuiting the direct-current bus throughout a first period of time and stopping short-circuiting the direct-current bus throughout a second period of time alternately.

In an embodiment, the preset pattern is that the voltage across the direct-current bus is zero throughout the first period of time, and is equal to a corresponding value throughout the second period of time.

In an embodiment, the method further includes: before the regulating, by the inverter system in the rapid shutdown system, the voltage across the direct-current bus in the rapid shutdown system, detecting, by the inverter system for each of the direct-current buses in the rapid shutdown system, a voltage across the direct-current bus; determining, by the inverter system for each of the direct-current buses, whether the voltage across the direct-current bus meets a preset abnormal condition; and sending an alarm by the inverter system, and regulating by the inverter system the voltage across the direct-current bus according to the preset abnormal condition, directly operating the inverter system without regulating the voltage across the direct-current bus, or stopping operating the inverter system, in a case that there is at least one direct-current bus among the direct-current buses whose voltage already meets the preset abnormal condition, wherein the voltage across the direct-current bus is regulated by the inverter system in a case that voltages respectively across all the direct-current buses do not meet the preset abnormal condition.

In an embodiment, the regulating by the inverter system the voltage across the direct-current bus according to the preset abnormal condition includes: limiting a pulse width to be within a preset range and short-circuiting the direct-current bus throughout the first period of time and stopping short-circuiting the direct-current bus throughout the second period of time, in a case that the voltage across the direct-current bus that already meets the preset abnormal condition is less than a first preset voltage.

In an embodiment, the directly operating the inverter system without regulating the voltage across the direct-current bus includes: keeping the rapid shutdown device connected to the direct-current bus off without short-circuiting the direct-current bus, in a case that the voltage across the direct-current bus that already meets the preset abnormal condition is greater than a second preset voltage, wherein the second preset voltage is greater than or equal to the first preset voltage.

In an embodiment, the method further includes: determining, by the rapid shutdown device based on a starting voltage of the rapid shutdown device instead of the voltage outputted by the rapid shutdown device, whether the change in the voltage across the direct-current bus meets the preset conduction condition.

In an embodiment, the regulating, by the inverter system, the voltage across the direct-current bus in a preset manner includes: converting the voltage across the direct-current bus throughout the first period of time, and stopping converting the voltage across the direct-current bus throughout the second period of time alternately.

In an embodiment, preset pattern is that the voltage across the direct-current bus has a preset value throughout the first period of time and is equal to a corresponding value throughout the second period of time, wherein the preset value is less than the corresponding value.

In a second aspect, a rapid shutdown device is provided according to the present disclosure. The rapid shutdown device includes a switch transistor unit, a starting voltage module, a driving circuit, a processor, a bypass diode, and a parameter collecting module. The switch transistor unit is arranged between a negative input terminal and a negative output terminal of the rapid shutdown device or is arranged between a positive input terminal and a positive output terminal of the rapid shutdown device, and is configured to turn on and turn off the rapid shutdown device under control of the processor. The parameter sampling module is configured to sample a state parameter and an output voltage of the rapid shutdown device and output the sampled state parameter and the sampled output voltage to the processor. The starting voltage module is configured to output, under the control of the processor, a starting voltage to an output end of the rapid shutdown device, in a case that the rapid shutdown device is off and the state parameter of the rapid shutdown device already meets a preset normal condition. The bypass diode is configured to provide a path bypass the rapid shutdown device in a case that the rapid shutdown device is off. An output terminal of the processor is connected to a control terminal of the switch transistor unit via the driving circuit. The processor is configured to, cooperating with the starting voltage module, the parameter sampling module, the driving circuit and the switch transistor unit, control the rapid shutdown device to: determine, based on the output voltage of the rapid shutdown device, whether a change in a voltage across a direct-current bus connected to the rapid shutdown device meets a preset conduction condition; and switch on in a case that the change in the voltage across the direct-current bus connected to the rapid shutdown device already meets the preset conduction condition.

In an embodiment, the rapid shutdown device is further configured to: determine whether the state parameter of the rapid shutdown device meets a preset normal condition; and output a preset starting voltage to the direct-current bus connected to the rapid shutdown device in a rapid shutdown system, in a case that the state parameter already meets the preset normal condition.

In an embodiment, the starting voltage module includes a low-voltage power supply, a first capacitor, and an anti-backflow diode. The low-voltage power supply is configured to output, under the control of the processor, the starting voltage through the anti-backflow diode, in a case that the rapid shutdown device is off and the state parameter already meets the preset normal condition, and the low-voltage power supply has internal resistance and is allowed to be short-circuited. A cathode of the anti-backflow diode serves as a positive output terminal of the starting voltage module, an anode of the anti-backflow diode is connected to an output terminal of the low-voltage power supply and a terminal of the first capacitor, and another terminal of the first capacitor serves as a negative output terminal of the starting voltage module. Alternatively, a cathode of the anti-backflow diode is connected to a terminal of the first capacitor, and a joint of the anti-backflow diode and the first capacitor serves as a positive output terminal of the starting voltage module, an anode of the anti-backflow diode is connected to an output terminal of the low-voltage power supply, and another terminal of the first capacitor serves as a negative output terminal of the starting voltage module.

In an embodiment, the parameter sampling module includes an input voltage sampling unit and an output voltage sampling unit. The input voltage sampling unit is configured to sample an input voltage of the rapid shutdown device. The output voltage sampling unit is configured to sample the output voltage of the rapid shutdown device.

In an embodiment, the parameter sampling module further includes a current collecting unit. The current sampling unit is arranged between the negative input terminal and the negative output terminal of the rapid shutdown device, and between an anode of the bypass diode and the negative output terminal of the rapid shutdown device. Alternatively, the current sampling unit is arranged between the negative input terminal and the negative output terminal of the rapid shutdown device, and between an anode of the bypass diode and the negative output terminal of the starting voltage module. Alternatively, the current sampling unit is arranged between the positive input terminal and the positive output terminal of the rapid shutdown device, and between a cathode of the bypass diode and the positive output terminal of the rapid shutdown device. Alternatively, the current sampling unit is arranged on the positive input terminal and the positive output terminal of the rapid shutdown device, and between a cathode of the bypass diode and the positive output terminal of the starting voltage module.

In an embodiment, the switching unit includes at least one switch transistor module. In a case of one switch transistor module, an input terminal of the switch transistor module serves as an input terminal of the switch transistor unit, an output terminal of the switch transistor module serves as an output terminal of the switch transistor unit, and a control terminal of the switch transistor module serves as a control terminal of the switch transistor unit. In a case of two or more switch transistor modules, an input terminal of a branch obtained by connecting all the switch transistor modules in series serves as the input terminal of the switch transistor unit, an output terminal of the branch serves as the output terminal of the switch transistor unit, and control terminals of all the switch transistor modules serve as the control terminal of the switch transistor unit.

In an embodiment, the parameter sampling module is further configured to sample a starting voltage at a starting voltage sampling point in the starting voltage module, and output the sampled starting voltage to the processor. The processor is further configured to control the rapid shutdown device to determine, based on a starting voltage of the rapid shutdown device instead of the output voltage of the rapid shutdown device, whether the change in the voltage across the direct-current bus connected to the rapid shutdown device meets the preset conduction condition.

In an embodiment, the parameter sampling module further includes: a starting voltage sampling unit configured to sample the starting voltage at the starting voltage sampling point in the starting voltage module.

In an embodiment, the starting voltage sampling point is near an anode of the anti-backflow diode in the starting voltage module.

In a third aspect, an inverting system is provided according to the present disclosure. The inverting system includes: a direct-current voltage control circuit and an inverter. The direct-current voltage control circuit is configured to regulate a voltage across a direct-current bus in a rapid shutdown system. The inverter is configured to cooperate with the direct-current voltage control circuit in the regulating the voltage across the direct-current bus in the rapid shutdown system.

In an embodiment, the inverter system is further configured to: detect the voltage across the direct-current bus in the rapid shutdown system, and determine whether the voltage across the direct-current bus meets a starting condition before regulating the voltage across the direct-current bus in the rapid shutdown system, wherein the voltage across the direct-current bus is regulated by the inverter system in a case that the voltage across the direct-current bus already meets the starting condition.

In an embodiment, the inverter system is further configured to, before regulating the voltage across the direct-current bus in the rapid shutdown system, detect, for each of direct-current buses in the rapid shutdown system, a voltage across the direct-current bus; determine, for each of the direct-current buses in the rapid shutdown system, whether the voltage across the direct-current bus meets a preset abnormal condition; and send an alarm, and regulate the voltage across the direct-current bus according to the preset abnormal condition, directly operate without regulating the voltage across the direct-current bus, or stop operating, in a case that there is at least one direct-current bus among the direct-current buses whose voltage already meets the preset abnormal condition, wherein the voltage across the direct-current bus is regulated by the inverter system in a case that voltages respectively across all the direct-current buses do not meet the preset abnormal condition.

In an embodiment, the direct-current voltage control circuit is a direct-current voltage controller independently arranged on the direct-current bus. The inverter includes an inverter circuit. A direct-current side of the inverter circuit serves as a direct-current side of the inverter; and an alternating-current side of the inverter circuit serves as an alternating-current side of the inverter.

In an embodiment, the direct-current voltage control circuit is a DC/DC circuit arranged in the inverter. The inverter further includes an inverter circuit. One side of the DC/DC circuit serves as a direct-current side of the inverter, the other side of the DC/DC circuit is connected to a direct-current side of the inverter circuit, and an alternating-current side of the inverting circuit serves as an alternating-current side of the inverter.

In an embodiment, the DC/DC circuit is a basic boost circuit or a three-level boost circuit.

In a fourth aspect, a rapid shutdown system is provided according to the present disclosure. The rapid shutdown system includes: at least one shutdown system and at least one inverter system according to the third aspect of the present disclosure. Each shutdown system includes a direct-current bus, at least N photovoltaic modules and N rapid shutdown devices according to the second aspect of the present disclosure. N is a positive integer. In each of the at least one shutdown system, output terminals of the N rapid shutdown devices are cascaded, and input terminals of the N rapid shutdown devices are connected to output terminals of the N photovoltaic modules, respectively. A positive terminal obtained after the output terminals of the N rapid shutdown devices are cascaded is connected to a positive terminal of a direct-current interface of the inverter system through a positive line of the direct-current bus. A negative terminal obtained after the output terminals of the N rapid shutdown devices are cascaded is connected to a negative terminal of the direct-current interface of the inverter system through a negative line of the direct-current bus.

It can be seen from the above technical solutions that the method for starting a rapid shutdown system is provided according to the present disclosure. An inverting system regulates a voltage across a direct-current bus in the rapid shutdown system. A rapid shutdown device connected to the direct-current bus determines, based on detected voltage outputted by itself, whether a change in the voltage across the direct-current bus meets a preset conduction condition. The rapid shutdown device switches on in response to its determination result that the voltage across the direct-current bus already meets the preset conduction condition. Therefore, the rapid shutdown device determines, via its own voltage sampling module only, whether a signal instructing to switch itself on is received, and no additional receiving module is involved. In this way, the rapid shutdown device can still communicate with external devices with low the costs in terms of hardware.

### BRIEF DESCRIPTION OF THE DRAWINGS

In order to more clearly illustrate technical solutions in embodiments of the present disclosure or in the conventional technology, the drawings to be used in the description of the embodiments or the conventional technology are briefly described below. Apparently, the drawings in the following description show only some embodiments of the present disclosure, and other drawings may be obtained by those skilled in the art from the drawings without any creative work.

FIG. 1 is a flow chart illustrating a method for starting a rapid shutdown system according to an embodiment of the present disclosure;

FIG. 2 is a flow chart illustrating a method for starting a rapid shutdown system according to another embodiment of the present disclosure;

FIG. 3 is a schematic diagram illustrating a voltage across a direct-current bus and a voltage outputted by a rapid shutdown device according to an embodiment of the present disclosure;

FIG. 4 is a schematic structural diagram illustrating a rapid shutdown system with a voltage across a direct-current bus and an output voltage of a rapid shutdown device according to an embodiment of the present disclosure;

FIG. 5 is a schematic structural diagram illustrating an equivalent circuit of a rapid shutdown system in case of malfunction according to an embodiment of the present disclosure;

FIG. 6 is a schematic diagram illustrating a shutdown device for a photovoltaic module according to another embodiment of the present disclosure;

FIG. 7 is a schematic diagram illustrating a rapid shutdown device according to another embodiment of the present disclosure;

FIG. 8 is a schematic diagram illustrating a rapid shutdown device according to another embodiment of the present disclosure;

FIG. 9 is a schematic diagram illustrating a rapid shutdown device according to another embodiment of the present disclosure;

FIG. 10 is a schematic diagram illustrating an inverter system in a rapid shutdown system according to an embodiment of the present disclosure;

FIG. 11 is a schematic diagram illustrating an inverter system in a rapid shutdown system according to another embodiment of the present disclosure;

FIG. 12 is a schematic diagram illustrating an inverter system in a rapid shutdown system according to another embodiment of the present disclosure;

FIG. 13 is a schematic diagram illustrating a rapid shutdown system according to an embodiment of the present disclosure;

FIG. 14 is a schematic diagram illustrating a rapid shutdown system according to another embodiment of the present disclosure;

FIG. 15 is a schematic diagram illustrating a rapid shutdown system according to another embodiment of the present disclosure;

FIG. 16 is a flow chart illustrating a method for starting a rapid shutdown system according to another embodiment of the present disclosure;

FIG. 17 is a schematic diagram illustrating an interference voltage and an output voltage of a rapid shutdown device according to an embodiment of the present disclosure;

FIG. 18 is a schematic diagram illustrating a rapid shutdown device according to another embodiment of the present disclosure;

FIG. 19 is a schematic diagram illustrating a starting voltage module in a rapid shutdown device according to an embodiment of the present disclosure;

FIG. 20 is a schematic diagram illustrating a rapid shutdown device according to another embodiment of the present disclosure; and

FIG. 21 is a schematic diagram illustrating a voltage across a direct-current bus and an output voltage of a rapid shutdown device according to another embodiment of the present disclosure.

### DETAILED DESCRIPTION

The technical solutions in the embodiments of the present disclosure are described clearly and completely hereinafter with reference to the drawings in the embodiments of the present disclosure, so that the objectives, technical solutions and advantages of the embodiments of the present disclosure are clearer. Apparently, the described embodiments are some rather than all of the embodiments of the present disclosure. All of other embodiments obtained by those skilled in the art based on the embodiments in the present disclosure without any creative work fall within the protection scope of the present disclosure.

The terms “include”, “comprise” or any other variants thereof are intended to be non-exclusive. Therefore, a process, method, article or device including a series of elements include not only these elements but also other elements that are not clearly enumerated, or further include elements inherent in the process, method, article or device. Unless expressively limited, the statement “including a . . . ” does not exclude the case that other similar elements may exist in the process, method, article or device including the series of elements.

A method for starting a rapid shutdown system is provided according to an embodiment of the present disclosure, so as to reduce the cost of the rapid shutdown device in terms of hardware compared with the conventional technology in which an additional receiving module is essential for the rapid shutdown device.

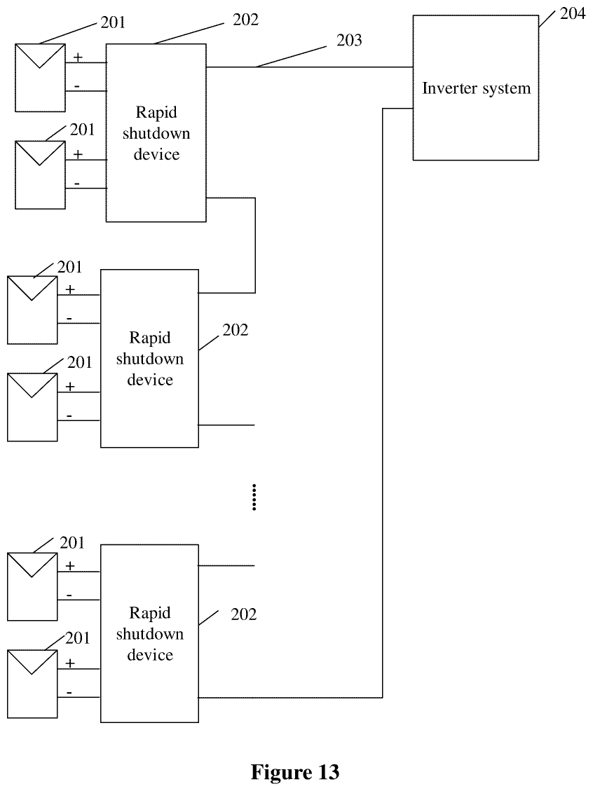

As shown in FIG. 13, the rapid shutdown system includes at least one shutdown subsystem and at least one inverter system 204. The shutdown subsystem includes a direct-current bus 203, at least N photovoltaic modules 201, and N rapid shutdown devices 202. N is a positive integer.

In the shutdown subsystem, output terminals of the N rapid shutdown devices 202 are cascaded. Input terminals of the N rapid shutdown devices 202 are connected to output terminals of the N photovoltaic modules 201, respectively. A positive terminal obtained by cascading the shutdown devices 202 is connected to a positive terminal of a corresponding direct-current interface of the inverting system 204 through a positive line of the direct-current bus 203. A negative terminal obtained by cascading the shutdown devices 202 is connected to a negative terminal of the corresponding direct-current interface of the inverting system 204 through a negative line of the direct-current bus.

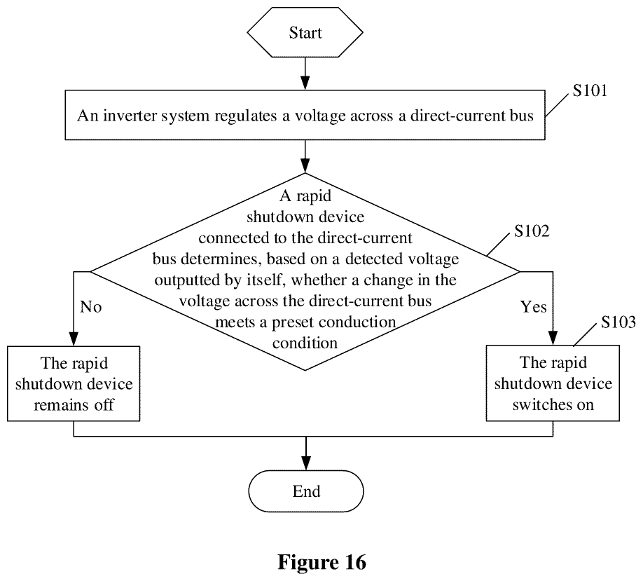

As shown in FIG. 16, the method for starting a rapid shutdown system includes the following steps S101 to S103.

In step S101, the inverter system regulates a voltage across the direct-current bus.

It should be noted that the inverter system regulates the voltage across the direct-current bus, so as to notify a rapid shutdown device connected to the direct-current bus of permission to be turned on.

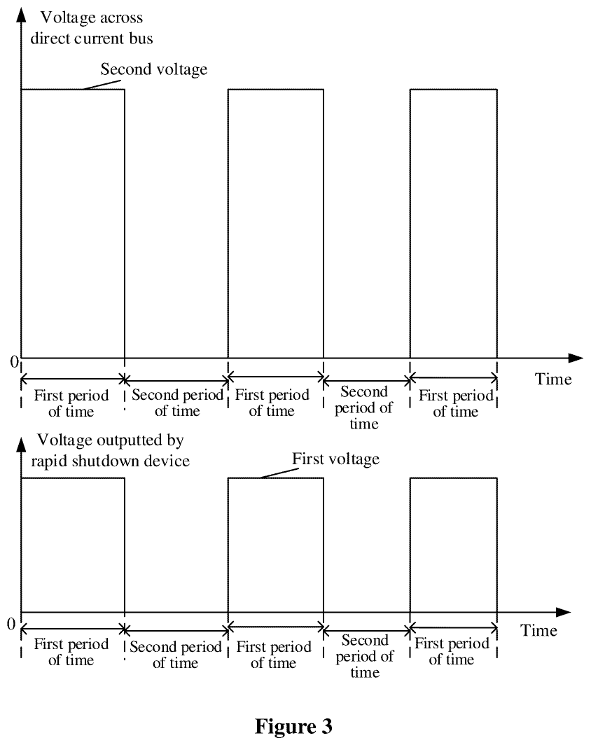

In practice, the inverter system regulates the voltage across the direct-current bus in a preset manner in step S101, such that the voltage of the direct-current bus changes following a predetermined trend. For example, the inverter system short-circuits the direct-current bus throughout a first period of time, and does not short-circuit the direct-current bus throughout a second period of time, where the first period of time alternates with the second period of time. Accordingly, the voltage of the direct-current bus is equal to zero throughout the first period of time, and has a corresponding voltage throughout the second period of time, for example, a second voltage. As shown in FIG. 3, the voltage of the direct-current bus remains at the second voltage throughout the second period of time. The direct-current bus is not short-circuited throughout the second period of time, and is short-circuited throughout the first period of time. It should be noted that the first period of time and the second period of time may alternate a preset number of times or may alternate constantly, depending on actual situations. It should be further noted that the first period of time and the second period of time may or may not be equal in length, depending on actual situations. All first periods of time may or may not be equal in length, depending on actual situations. Likewise, all second periods of time may or may not be equal in length, depending on actual situations.

It should be noted that the first period of time and the second period of time are agreed upon between the inverter system and the rapid shutdown device. Further, the preset number of times is agreed upon between the inverter system and the rapid shutdown device.

In step S102, the rapid shutdown device determines, based on a detected voltage outputted by itself, whether a change in the voltage of the direct-current bus connected to the rapid shutdown device complies with a predetermined conduction condition.

In a case that the change in the voltage of the direct-current bus connected to the rapid shutdown device already complies with the predetermined conduction condition, step S103 is performed. In a case that the change in the voltage of the direct-current bus does not comply with the predetermined conduction condition, the rapid shutdown device remains off.

In step S103, the rapid shutdown device is controlled to be turned on.

The preset conduction condition is that the direct-current bus outputs short pulses, which means that the direct-current bus is short-circuited and then is not short-circuited. The direct-current bus may be short-circuited and not short-circuited alternately. Accordingly, the change in the voltage outputted by the rapid shutdown device is shown in FIG. 3. When the direct-current bus is not short-circuited, the voltage of the direct-current bus remains at the second voltage, and the rapid shutdown device outputs a first voltage. When the direct-current bus is short-circuited, the voltage of the direct-current bus is zero, and the rapid shutdown device outputs a voltage of zero. It should be noted that the direct-current bus may be alternately short-circuited and not short-circuited a preset number of times. For example, when it is detected that the direct-current bus has been alternately short-circuited and not short-circuited the preset number of times, the rapid shutdown device is turned on. The preset number of times may be two or more times, depending on actual situations.

With the above technical solutions, the direct-current bus is alternately short-circuited and not short-circuited by the inverter system, so that a voltage outputted by each rapid shutdown device alternates between a preset starting voltage and zero. When the direct-current bus is alternately short-circuited and not short-circuited several times, the direct-current bus outputs the short pulses. The rapid shutdown device switches, when detecting the short pulses based on the voltage outputted by itself, itself on, and therefore the photovoltaic module connected to the rapid shutdown device outputs electric power. In this way, the rapid shutdown device can determine whether a conduction signal is received through only a voltage sampling device inherent in itself, and therefore the rapid shutdown device is provided with receiving module, so that the cost of the rapid shutdown device can be reduced in terms of hardware without affecting the communication between the rapid shutdown device and an external device. Correspondingly, the inverter system is further provided with no module for sending the conduction signal, thereby reducing the cost of the inverter system in terms of hardware. In addition, the voltage and the current that result in low power are applied in the present disclosure, so as to effectively solve the problem that the power line carrier communication, wireless communication and the like are prone to interference, thereby improving the stability of the rapid shutdown system.

It can be seen from the relevant explanations of steps S102 and S103 that the rapid shutdown device can switches itself on based on the voltage outputted by itself.

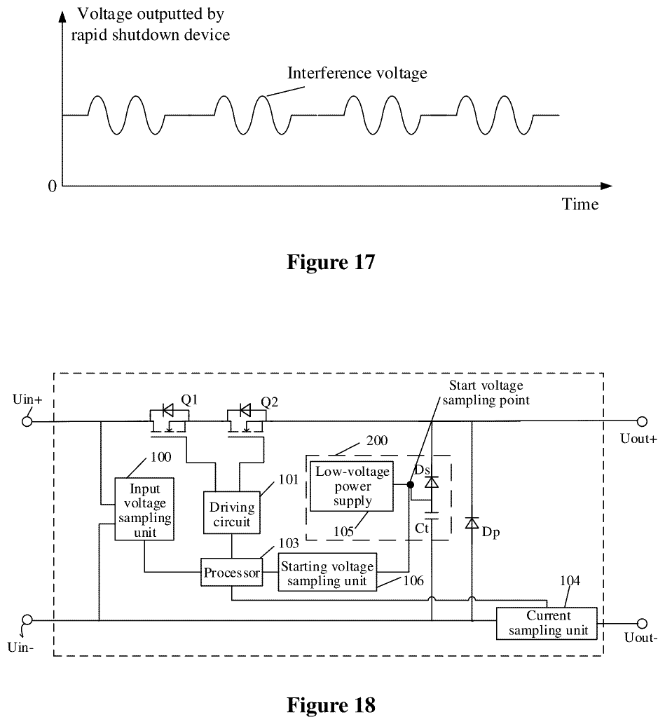

According to relevant requirements, for example, the Code 690.12 in NEC 2017, a voltage between conductors located more than one meter from a point of entry inside a building shall be limited to not more than 30V within 30 seconds of rapid shutdown initiation. In order to meet these requirements, a minimum starting voltage of the rapid shutdown device is normally a low direct-current voltage. For example, in a photovoltaic system including twenty rapid shutdown devices connected in series, the minimum starting voltage of each of the rapid shutdown devices is less than a voltage (30/20)V. The rapid shutdown device, when detecting a change in its outputted voltage which is susceptible to interference due to the low minimum starting voltage, likely makes determination incorrectly. For example, FIG. 3 is a schematic diagram illustrating the voltage outputted by the rapid shutdown device when normally turned on based on the outputted voltage. FIG. 17 illustrates a waveform of the voltage outputted by the rapid shutdown device in the presence of an interference voltage. That is, the rapid shutdown device is likely turned on erroneously due to the interference voltage shown in FIG. 17.

Alternatively, the rapid shutdown device determines, based on the detected starting voltage of itself, whether the change in the voltage of the direct-current bus connected to itself meets the preset conduction condition in step S102.

In a case that the change in the voltage of the direct-current bus connected to itself already meets the preset conduction condition, step S103 is performed. In a case that the change in the voltage of the direct-current bus connected to itself does not meet the preset conduction condition, the rapid shutdown device remains off.

In the embodiment, the rapid shutdown device switches itself on based on the detected starting voltage of itself rather than the detected voltage outputted by itself, and therefore is effectively prevented from switching itself on erroneously due to the interference in the outputted voltage. Therefore, the rapid shutdown device determines, based on the detected starting voltage of itself, whether the change in the voltage of the direct-current bus connected to itself meets the preset conduction condition preferably in step S102.

In the following descriptions, the voltage outputted by the rapid shutdown device may be replaced with the starting voltage of the rapid shutdown device, which is not repeated in the present disclosure. All the implementations fall within the protection scope of the present disclosure.

In practice, there is always a certain amount of power on the direct-current bus. Therefore, the voltage across the direct-current bus is generally higher than zero during the first period of time as the voltage of the direct-current bus changes. That is, the voltage across the direct-current bus has a preset value throughout the first period of time, and has the corresponding value throughout the second period of time.

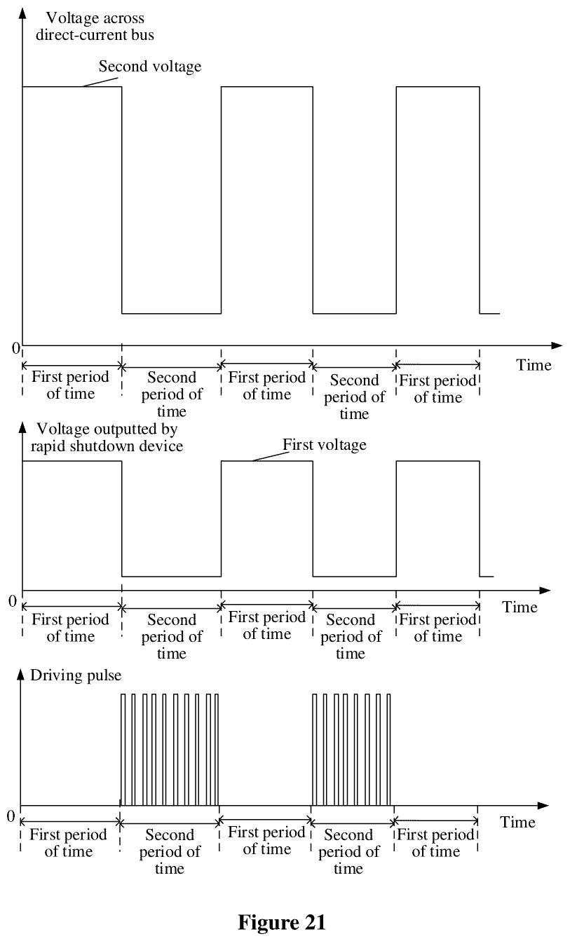

As shown in FIG. 21, the voltage across the direct-current bus is higher than zero and lower than the second voltage during the first period of time, and generally approximates to zero. The preset value is not limited herein and depends on the actual situations. All the implementations fall within the protection scope of the present disclosure.

In practice, an inverter in the inverter system in the rapid shutdown system alternately converts the voltage across the direct-current bus and does not convert the voltage across the direct-current bus instead of alternately short-circuiting the direct-current bus and not short-circuiting the direct-current bus as discussed in step S101.

In an embodiment, the inverter system converts the voltage across the direct-current bus throughout a first period of time, and does not converts the voltage across the direct-current bus throughout a second period of time, where the first period of time alternates with the second period of time. The voltage across the direct-current bus during the first period of time is less than the voltage across the direct-current bus during the second period of time.

As shown in FIG. 21, the voltage across the direct-current bus remains at a second voltage when not converted by the inverter system. It should be noted that the first period of time and the second period of time may alternate a preset number of times or may alternate constantly, depending on actual situations. It should be further noted that the first period of time and the second period of time may or may not be equal in length, depending on actual situations. All first periods of time may or may not be equal in length, depending on actual situations. Likewise, all second periods of time may or may not be equal in length, depending on actual situations. All the implementations fall within the protection scope of the present disclosure.

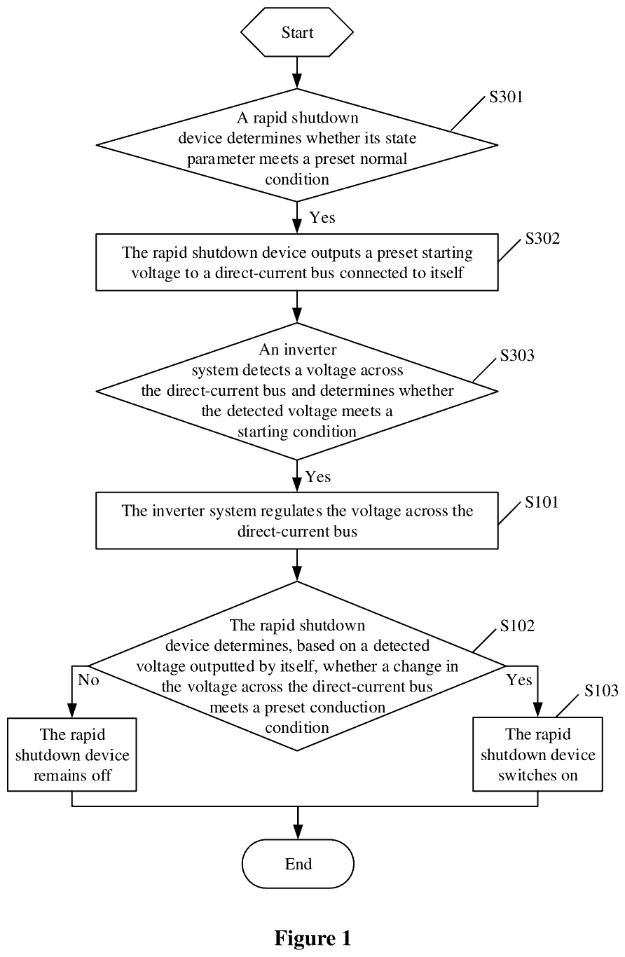

In addition, as shown in FIG. 1, the method further includes the following steps S301 to S303 before step S101.

In step S301, the rapid shutdown device determines whether a detected state parameter of itself meets a preset normal condition.

In a case that the state parameter meets the preset normal condition, step S302 is performed.

In step S302, the rapid shutdown device outputs a preset starting voltage to the direct-current bus connected to itself.

It should be noted that the state parameter includes at least one of an input current, an input voltage, and a temperature. The input voltage is taken as an example for description. The rapid shutdown device that is off outputs, in response to the fact that the photovoltaic module connected to itself is outputting a voltage not zero to itself, e.g., at sunrise, the preset starting voltage to the direct-current bus connected to itself so as to notify the inverter system that the photovoltaic module already outputs the voltage. However, the rapid shutdown device does not trigger a starting process of the inverter system, that is, does not output the preset starting voltage to the inverter system at nighttime or when the photovoltaic module malfunctions, e.g., when the photovoltaic module is in shade or is damaged, and therefore outputs no voltage. The preset normal condition may be that the state parameter of the rapid shutdown device is greater than a preset state parameter. The preset state parameter is not limited herein but depends on the actual situations. The state parameter may further be in other forms which are not described in detail herein but depend on the actual situations. All the implementations fall within the protection scope of the present disclosure.

In practice, a sum of starting voltages outputted by all rapid shutdown devices connected the same direct-current bus is less than a preset voltage. Therefore, the voltage across the direct-current bus remains relatively low until the inverter system allows all rapid shutdown devices connected to the same direct-current bus to be turned on. A preset starting voltage is normally a direct-current voltage of 1V. Further, the preset starting voltage may be other direct-current voltage or alternating-current voltage of another amplitude. The preset voltage is a voltage specified in the relevant standards, e.g., 30V in NEC2017. In addition, the preset voltage may be set to other value, which is not described in detail herein. All the implementations fall within the protection scope of the present disclosure.

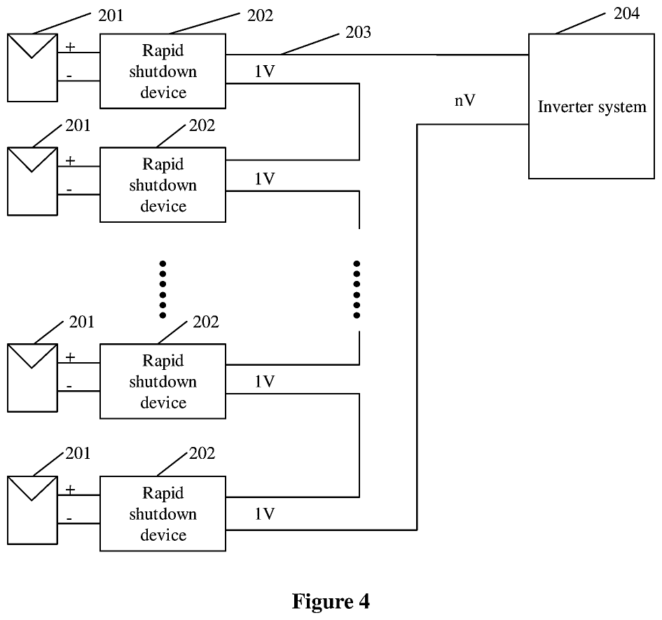

FIG. 4 is a structural diagram illustrating the rapid shutdown system together with corresponding voltages, in order to introduce a relation between the starting voltage outputted by each of the rapid shutdown devices and the voltage across the direct-current bus. Each of the rapid shutdown devices, when ready, that is, when the state parameter of the rapid shutdown device already meets the preset normal condition, outputs the direct-current voltage of 1V. The rapid shutdown system includes N rapid shutdown devices connected to respective photovoltaic modules. All the N rapid shutdown devices each, when being ready, output the direct-current voltage of 1V. The voltages outputted by the N rapid shutdown devices are all across the direct-current bus. That is, the voltage finally across the direct-current bus is Ub of NV.

In step S303, the inverter system detects the voltage across the direct-current bus and determines whether the voltage across the direct-current bus meets a starting condition.

The starting condition may be that the number of the rapid shutdown devices that have outputted the starting voltages is greater than or equal to a preset number. The number of the rapid shutdown devices here is acquired based on the voltage across the direct-current bus. In addition, the starting condition may further be other condition indicating that the rapid shutdown system is to be started, which are not described in detail herein. All the implementations fall within the protection scope of the present disclosure.

In practice, the inverter system first detects the voltage across the direct-current bus, then determines the number of the rapid shutdown devices based on the voltage across the direct-current bus, and finally determines whether the determined number of the rapid shutdown devices is greater than or equal to the preset number. The inverter system determines that the voltage across the direct-current bus already meets the starting condition when determined that the determined number of the rapid shutdown devices is greater than or equal to the preset number. The inverter system determines that the voltage across the direct-current bus does not meet the starting condition when determined that the number of the rapid shutdown devices is less than the preset number. The preset number depends on the actual situations, and thus is not described in detail herein. All the implementations fall within the protection scope of the present disclosure.

In a distributed photovoltaic system, the number of photovoltaic modules connected in series on the direct-current bus normally does not exceed thirty. For example, the starting voltage is a constant at Ux, and the inverter system detects that the voltage across the direct-current bus is Ub. The inverter system determines that the number of the rapid shutdown devices that have outputted starting voltages to the direct-current bus is Nx=Ub/Ux. Next, the inverter system determines whether Nx is greater than or equal to the preset number. In a case that Nx is greater than or equal to the preset number, the voltage across the direct-current bus already meets the starting condition. In a case that Nx is less than the preset number, the voltage across the direct-current bus does not meet the starting condition. In a case that the voltage across the direct-current bus meets the starting condition, the step S101 is performed. It should be noted that in a case that the voltage across the direct-current bus is greater than a maximum direct-current state parameter allowed by the inverter system, the inverter system determines that the voltage across the direct-current bus is abnormal. In this case, the inverter system likely stops operating. That is, the step S101 is not performed.

The rapid shutdown device outputs no starting voltage at nighttime or when the photovoltaic module malfunctions. Accordingly, the inverter system does not frequently perform a starting operation, that is, does not frequently regulate the voltage across the direct-current bus.

In the embodiment, the rapid shutdown device notifies the inverter system, by outputting the starting voltage to the inverter system, that the photovoltaic module already outputs high electric power. The inverter system regulates the voltage across the direct-current bus after determining that the voltage across the direct-current bus meets the preset starting condition. In this way, the inverter system does not regulate the voltage across the direct-current bus until the rapid shutdown device successfully responds, thereby improving the operating efficiency of the inverter system.

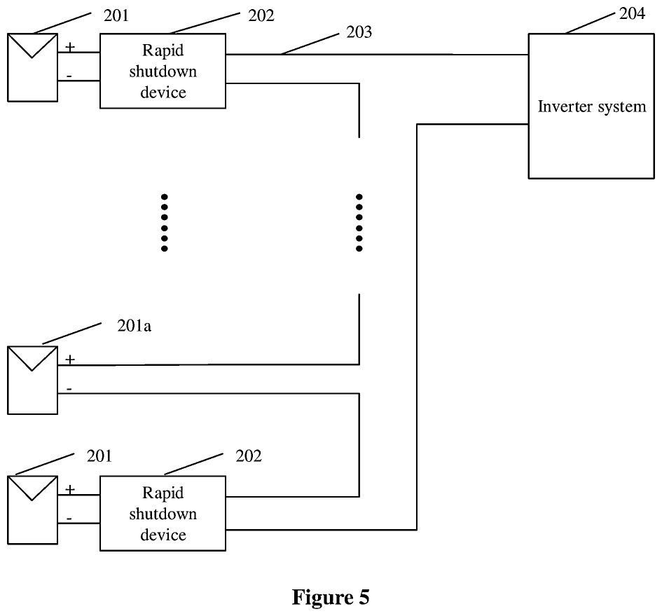

It should be noted that the rapid shutdown system may be in a structure as shown in FIG. 5, in which at least one photovoltaic module (for example, 201a as shown in FIG. 5) is connected to no rapid shutdown device 202. Alternatively, at least one rapid shutdown device 202 in the rapid shutdown system may malfunction, and thus fails to be turned off. In such case, a voltage outputted by the photovoltaic module (for example, 201a as shown in FIG. 5) is directly applied to the direct-current bus 203 without being controlled by the rapid shutdown system. In this case, the voltage across the direct-current bus 203 likely exceeds the limit specified in the standards once other photovoltaic module 202 are turned on, resulting in damages to the rapid shutdown system.

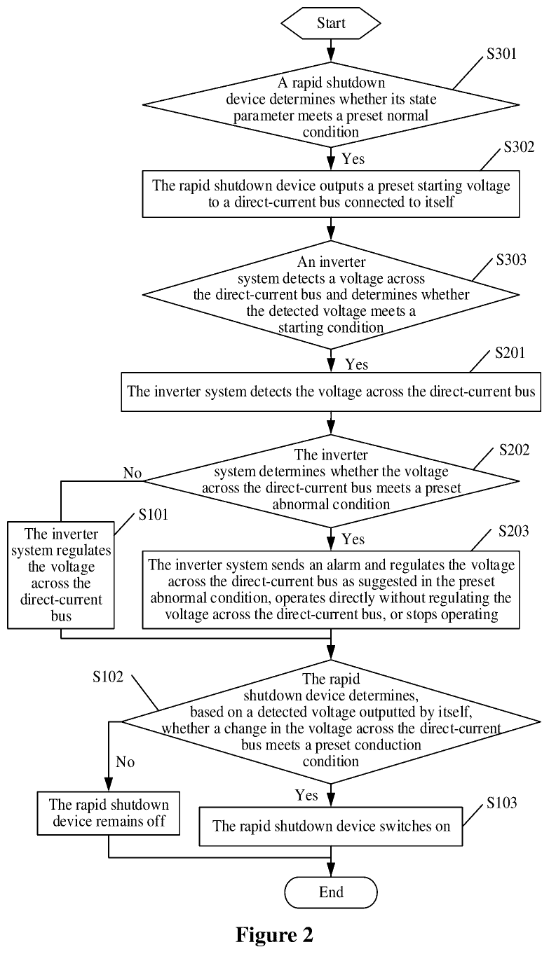

Therefore, the method further includes the following steps S201 to S203 before step S101 in practice, as shown in FIG. 2 (drawn based on FIG. 1).

In step S201, the inverter system detects, for each of direct-current buses in the rapid shutdown system, a voltage across the direct-current bus.

In step S202, the inverter system determines whether the detected voltage meets a preset abnormal condition.

The preset abnormal condition may be that the voltage across the direct-current bus is greater than a preset voltage. The preset voltage may be a maximum voltage in a case that all rapid shutdown devices connected to the direct-current bus are off, or depends on the actual situations. Details about the preset abnormal condition is not limited herein but depends on the actual situations All the implementations fall within the protection scope of the present disclosure.

In a case that there is at least one direct-current bus whose voltage meets the preset abnormal condition, step S203 is performed. In a case of no direct-current bus whose voltage meets the preset abnormal condition, step S101 is performed.

In step S203, the inverter system sends an alarm, and regulates the voltage across the direct-current bus according to the preset abnormal condition, operates directly without regulating the voltage of the direct-current bus, or stops operating.

The inverter system sends the alarm by, for example, limiting the outputted power, switching on a fault indicator, reporting fault codes through communication, and sending an alarm message through a network platform, depending on the actual situations, and which are not described in detail herein All the implementations fall within the protection scope of the present disclosure.

After sending the alarm, the inverter system determines based on settings whether to stop operating. The solution of stopping operating the inverter system can secure the whole system against damages, however, at the expense of power production. Instead, after sending the alarm, the inverter system still operates as described in the following two cases.

(1) In the first case, the inverter system regulates the voltage of the direct-current bus according to the preset abnormal condition. That is, in a case that the voltage across the direct-current bus that already meets the preset abnormal condition is less than a first preset voltage, a pulse width is limited within a preset range and the direct-current bus is short-circuited throughout the first period of time, and the direct-current bus is not short-circuited throughout the second period of time.

The first preset voltage is a minimum voltage for starting the inverter system. It should be noted that the voltage across the direct-current bus, when less than the minimum voltage, fails to meet the requirements for starting the rapid shutdown system. It is necessary in such case to turn on a rapid shutdown device connected to the direct-current bus, so that electric power outputted by the photovoltaic module connected to the rapid shutdown device can be applied to the direct-current bus. Therefore, the voltage across the direct-current bus can meet demands of the rapid shutdown system. The inverter system limits the pulse width when the direct-current bus is short-circuited, in order to secure components from damages resulted from overcurrent. The preset range is not limited herein but depends on the actual situations. All the implementations fall within the protection scope of the present disclosure.

(2) In the second case, the inverter system operates directly without regulating the voltage across the direct-current bus. In a case that the voltage across the direct-current bus that already meets the preset abnormal condition is greater than a second preset voltage, the direct-current bus is not short-circuited, such that the rapid shutdown device connected to the direct-current bus remains off.

The second preset voltage is greater than or equal to the first preset voltage. That is, the second preset voltage may be equal to the first preset voltage, that is, also the minimum voltage for starting the inverter system. Alternatively, the second preset voltage is different from the first preset voltage. Whether the second preset voltage is greater than or equal to the first preset voltage is not limited herein and depends on the actual situations. All the implementations fall within the protection scope of the present disclosure. Details about the second preset voltage is not limited herein, as long as the sum of voltages outputted by the photovoltaic module connected to the rapid shutdown device that fails to be turned off and by the photovoltaic module provided with no rapid shutdown device is sufficient for starting the inverter system when the voltage across the direct-current bus is greater than the second preset voltage. In such case, the inverter system may directly operate. Then, whether to stop operating the inverter system or turn on other rapid shutdown device depends on the settings, varying from situation to situation. All the implementations fall within the protection scope of the present disclosure.

It should be noted that FIG. 2 only illustrates an example, in which steps S201 and S202 is performed after steps S301, S302 and S303 and before step S101. The above steps may be performed differently, which is not descried in detail herein but depends on the actual situation. All the implementations fall within the protection scope of the present disclosure.

In the embodiment, before regulating the voltage of the corresponding direct-current bus, the inverter system determines, for each of direct-current buses, whether the voltage across the direct-current bus meets the preset abnormal condition. The inverter system sends the alarm in response to its determination that the voltage across the direct-current bus meets the preset abnormal condition, so as to prevent the rapid shutdown device from being directly turned on. In this way, the voltage across the direct-current bus cannot exceed the limit specified in the standards, thereby securing the rapid shutdown system.

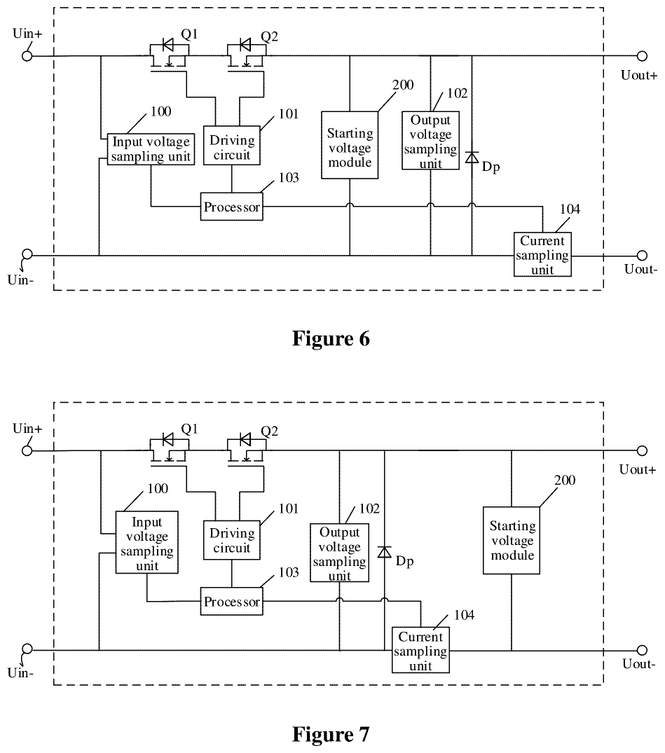

A rapid shutdown device is provided according to an embodiment of the present disclosure. As shown in FIG. 6, the rapid shutdown device includes a switch transistor unit (including switch transistor modules Q1 and Q2 as shown in FIG. 6), a starting voltage module 200, a driving circuit 101, a processor 103, a bypass diode Dp and a parameter sampling module (including an input voltage sampling unit 100, an output voltage sampling unit 102 and a current sampling unit 104 as shown in FIG. 6).

The switch transistor unit is arranged between a negative input terminal and a negative output terminal of the rapid shutdown device (not shown in the drawings). Alternatively, the switching unit is arranged between a positive input terminal and a positive output terminal of the rapid shutdown device (as shown in FIG. 6). In such case, an input terminal of the switch transistor module Q1 serves as an input terminal of the switch transistor unit, and is connected to a positive input terminal Uin+ of the rapid shutdown device. An output terminal of the switch transistor module Q1 is connected to an input terminal of the switch transistor module Q2. An output terminal of the switch transistor module Q2 serves as an output terminal of the switch transistor unit. The switch transistor unit is configured to turn on and turn off the rapid shutdown device as instructed by the processor 103.

The switch transistor unit includes at least one switch transistor module (FIG. 6 illustrates an example in which the switch transistor unit includes two switch transistors). In a case that the switch transistor unit includes one switch transistor, an input terminal of the switch transistor module serves as the input terminal of the switch transistor unit, an output terminal of the switch transistor module serves as the output terminal of the switch transistor unit, and a control terminal of the switch transistor module serves as a control terminal of the switch transistor unit (not shown in the drawings). In a case that the switch transistor unit includes more than one switch transistor module, an input terminal of a branch formed by all the switch transistor modules connected in series serves as the input terminal of the switch transistor unit, an output terminal of the branch serves as the output terminal of the switch transistor unit, and control terminals of all the switch transistor modules serve as the control terminal of the switch transistor unit. As in the example shown in FIG. 6 where the switch transistor unit includes two switch transistor modules, the input terminal of the switch transistor module Q1 serves as the input terminal of the switch transistor unit, and is connected to the positive input terminal Uin+ of the rapid shutdown device. The output terminal of the switch transistor module Q1 is connected to the input terminal of the switch transistor module Q2. The output terminal of the switch transistor module Q2 serves as the output terminal of the switch transistor unit. The control terminals of the switch transistor modules Q1 and Q2 serve as the control terminal of the switch transistor unit.

Each switch transistor module includes at least one switch transistor (FIG. 6 illustrates an example in which the switch transistor module includes one switch transistor). In a case that the switch transistor module includes more than one switch transistor, all the switch transistors are connected in parallel and/or in series. The switch transistor is a semiconductor device, for example, a MOSFET (metal-oxide-semiconductor field-effect transistor), or an IGBT (insulated gate bipolar transistor). FIG. 6 illustrates the MOSFET. The IGBT is not shown in the drawings herein. All implementations fall within the protection scope of the present disclosure.

The parameter sampling module is configured to collect a state parameter and an output voltage of the rapid shutdown device, and output the sampled state parameter and the sampled output voltage to the processor 103.

The parameter sampling module includes the input voltage sampling unit 100 and the output voltage sampling unit 102. The input voltage sampling unit 100 is arranged between the positive input terminal and the negative input terminal of the rapid shutdown device. Specifically, a positive input terminal and a negative input terminal of the input voltage sampling unit 100 are connected to the positive input terminal and the negative input terminal of the rapid shutdown device, respectively. An output terminal of the input voltage sampling unit 100 is connected to the processor 103. The input voltage sampling unit 100 is configured to collect a voltage inputted to the rapid shutdown device, and output the sampled voltage to the processor 103. The output voltage sampling unit 102 is arranged between a positive output terminal and a negative output terminal of the rapid shutdown device. Specifically, a positive input terminal and a negative input terminal of the output voltage sampling unit 102 are connected to the positive output terminal and the negative output terminal of the rapid shutdown device, respectively. An output terminal of the output voltage sampling unit 102 is connected to the processor 103. The output voltage sampling unit 102 is configured to sample a voltage outputted by the rapid shutdown device and output the sampled voltage to the processor 103.

In practice, the parameter sampling module is further configured to sample an output current of the rapid shutdown device. Accordingly, the parameter sampling module further includes the current sampling unit 104. In a case that the switch transistor unit is on, the bypass diode Dp is cut off, and the current sampling unit 104 samples the current outputted by the photovoltaic module. In a case that the switch transistor unit is off, the current sampling unit 104 samples a current flowing through the bypass diode Dp.

Generally, the current sampling unit 104 has small impedance, and thus may be connected in various manners, four of which are described below.

(1) As shown in FIG. 6, the current sampling unit 104 is arranged between the negative input terminal and the negative output terminal of the rapid shutdown device, and between an anode of the bypass diode Dp and the negative output terminal Uout− of the rapid shutdown device. Specifically, a terminal of the current sampling unit 104 is connected to the negative output terminal Uout− of the rapid shutdown device, and another terminal of the current sampling unit 104 is connected to the anode of the bypass diode Dp and the negative input terminal Uin− of the rapid shutdown device.

(2) As shown in FIG. 7, the current sampling unit 104 is arranged between the negative input terminal and the negative output terminal of the rapid shutdown device, and between the anode of the bypass diode Dp and a negative output terminal of the starting voltage module 200. Specifically, a terminal of the current sampling unit 104 is connected to the anode of the bypass diode Dp and the negative input terminal Uin− of the rapid shutdown device, and another terminal of the current sampling unit 104 is connected to the negative output terminal of the starting voltage module 200 and the negative output terminal Uout− of the rapid shutdown device.

(3) The current sampling unit 104 is arranged between the positive input terminal and the positive output terminal of the rapid shutdown device, and between a cathode of the bypass diode Dp and the positive output terminal Uout+ of the rapid shutdown device. Specifically, a terminal of the current sampling unit 104 is connected to the positive output terminal Uout+ of the rapid shutdown device, and another terminal of the current sampling unit 104 is connected to the cathode of the bypass diode Dp (not shown in the drawings).

(4) The current sampling unit 104 is arranged between the positive input terminal and the positive output terminal of the rapid shutdown device, and between the cathode of the bypass diode Dp and a positive output terminal of the starting voltage module 200.

Specifically, a terminal of the current sampling unit 104 is connected to the positive output terminal Uout+ of the of the rapid shutdown device and the positive output terminal of the starting voltage module 200, and another terminal of the current sampling unit 104 is connected to the cathode of the bypass diode Dp (not shown in the drawings).

The positive output terminal and the negative output terminal of the starting voltage module 200 are connected to the positive output terminal and the negative output terminal of the rapid shutdown device, respectively. The starting voltage module 200 is configured to output, as instructed by the processor 103, a starting voltage to the output end of the rapid shutdown device, in a case that the rapid shutdown device is off and the state parameter of the rapid shutdown device meets the preset normal condition. It should be noted that the starting voltage module 200 has internal resistance, and thus the starting voltage module may be short-circuited at its output end. Therefore, the starting voltage module 200 outputs no voltage when short-circuited.

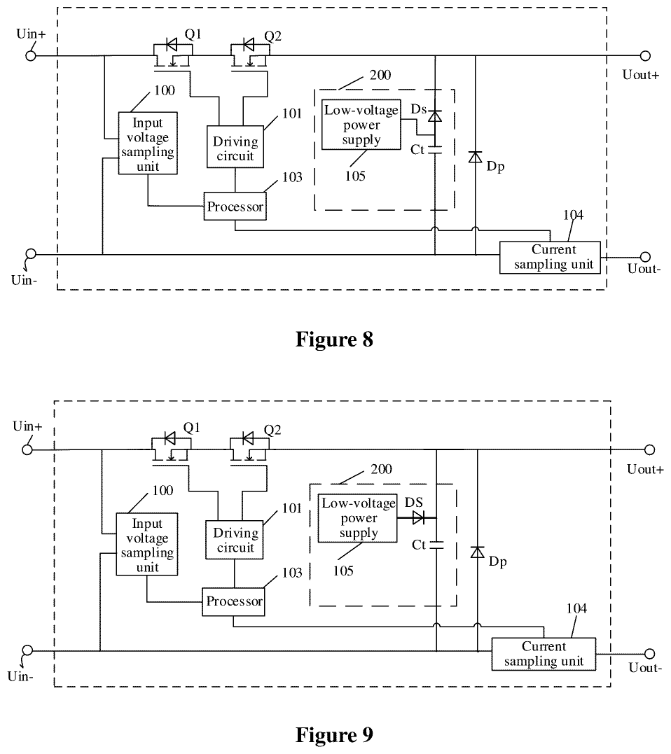

In practice, as shown in FIGS. 8 and 9 (neither of which shows the output voltage sampling unit 102), the starting voltage module 200 includes a low-voltage power supply 105, a first capacitor Ct, and an anti-backflow diode Ds.

The low-voltage power supply 105 has internal resistance and is allowed to be short-circuited. The low-voltage power supply 105 is configured to output, as instructed by the processor 103, the starting voltage through the anti-backflow diode Ds, in a case that the rapid shutdown device is off and the state parameter of the rapid shutdown device meets the preset normal condition.

As shown in FIG. 8, a cathode of the anti-backflow diode Ds serves as the positive output terminal of the starting voltage module 200, and an anode of the anti-backflow diode Ds is connected to an output terminal of the low-voltage power supply 105 and a terminal of the first capacitor Ct. Another terminal of the first capacitor Ct serves as the negative output terminal of the starting voltage module 200. Alternatively, as shown in FIG. 9, the cathode of the anti-backflow diode Ds is connected to a terminal of the first capacitor Ct, and a common terminal of the anti-backflow diode Ds and the first capacitor Ct serves as the positive output terminal of the starting voltage module 200. The anode of the anti-backflow diode Ds is connected to the output terminal of the low-voltage power supply 105. Another terminal of the first capacitor Ct serves as the negative output terminal of the starting voltage module 200.

The anode of the bypass diode Dp is connected to the negative output terminal Uout− of the rapid shutdown device, and the cathode of the bypass diode Dp is connected to the positive output terminal Uout+ of the rapid shutdown device. The bypass diode Dp is configured to provide a path bypass the rapid shutdown device in a case that the rapid shutdown device 202 is off.

An output terminal of the processor 103 is connected to the control terminal of the switch transistor unit via the driving circuit 101. The processor 103 is configured to control, cooperating with the starting voltage module 200, the parameter sampling module, the driving circuit 101 and the switch transistor unit, the rapid shutdown device to implement the method for starting a rapid shutdown system described in the above embodiments, specifically: determining based on a detected voltage outputted by the rapid shutdown device whether a change in a voltage of a direct-current bus connected to the rapid shutdown device meets a preset conduction condition; and controlling, in response to the determination that the change in the voltage across the direct-current bus connected to the rapid shutdown device meets the preset conduction condition, the rapid shutdown device to be turned on. In practice, the rapid shutdown device is further configured to: determine whether an acquired state parameter of the rapid shutdown device meets a preset normal condition; and output, in response to the determination that the acquired state parameter meets the preset normal condition, a preset starting voltage to the direct-current bus connected to the rapid shutdown device.

It should be noted that details that the rapid shutdown device performs the method for starting the rapid shutdown system may refer to the description of the method rapid shutdown system according to the forgoing embodiments, and are not repeated here.

In the embodiments, the rapid shutdown device can turn itself on and off based on its state parameter and its output voltage acquired by its parameter sampling module, involving neither communication signal nor additional signal receiving module for receiving an on-off communication signal outputted by the inverter system, thereby reducing the costs of the rapid shutdown device in terms of hardware.

It should be noted that the parameter sampling module is further configured to sample a starting voltage at a starting voltage sampling point in the starting voltage module 200, and output the sampled starting voltage to the processor 103. In such case, the parameter sampling module does not sample the output voltage. That is, the parameter sampling module samples at least one of the starting voltage and the output voltage, in addition to the input voltage. For example, the parameter sampling module samples only the input voltage and the output voltage. Alternatively, the parameter sampling module samples only the input voltage and the starting voltage. Alternatively, the parameter sampling module samples the input voltage, the output voltage, and the starting voltage. Details about the parameter collection module is not limited herein, but depends on the actual situations. All the implementations fall within the protection scope of the present disclosure.

As shown in FIG. 18, the parameter sampling module further includes a starting voltage sampling unit 106. The starting voltage sampling unit 106 is arranged at the starting voltage sampling point in the starting voltage module 200. A terminal of the starting voltage sampling unit 106 is connected to the sampling voltage sampling point, and another terminal of the starting voltage sampling unit 106 is connected to the processor 103. The starting voltage sampling unit 106 is configured to sample the starting voltage in the starting voltage module 200 and output the sampled starting voltage to the processor 103.

The starting voltage sampling point is near the anti-backflow diode Ds. As shown in FIG. 8, for example, the anode of the anti-backflow diode Ds, the output terminal of the low-voltage power supply 105, and the terminal of the first capacitor Ct are connected at the starting voltage sampling point. That is, the common terminal between the anode of the anti-backflow diode Ds, the output terminal of the low-voltage power supply 105, and the terminal of the first capacitor Ct are connected to the processor 103 via the starting voltage collection unit 106 (as shown in FIG. 18). As shown in FIG. 9, the anode of the anti-backflow diode Ds and the output terminal of the low-voltage power supply 105 are connected at the starting voltage sampling point. That is, the common terminal between the anode of the anti-backflow diode Ds and the output terminal of the low-voltage power supply 105 is connected to the processor 103 via the starting voltage collection unit 103 (not shown in the diagrams).

The starting voltage module 200 is provided with the starting voltage sampling point, and the starting voltage sampling point is near the anti-backflow diode Ds. The anti-backflow diode Ds can eliminate an interference voltage when the output voltage of the rapid shutdown device is greater than an output voltage of the low-voltage power supply 105, and the first capacitor Ct can filter an interference voltage when the output voltage of the rapid shutdown device is less than the output voltage of the low-voltage power supply 105. Therefore, the starting voltage at the starting voltage sampling point cannot be affected even if another device interferes with the output voltage of the rapid shutdown device.

The output voltage of the low-voltage power supply 105 is normally less than the direct-current voltage of 1.5V, and the first capacitor Ct has a low withstand voltage. Therefore, the first capacitor Ct is generally a low-voltage multilayer capacitor with low cost, small package, and large capacity.

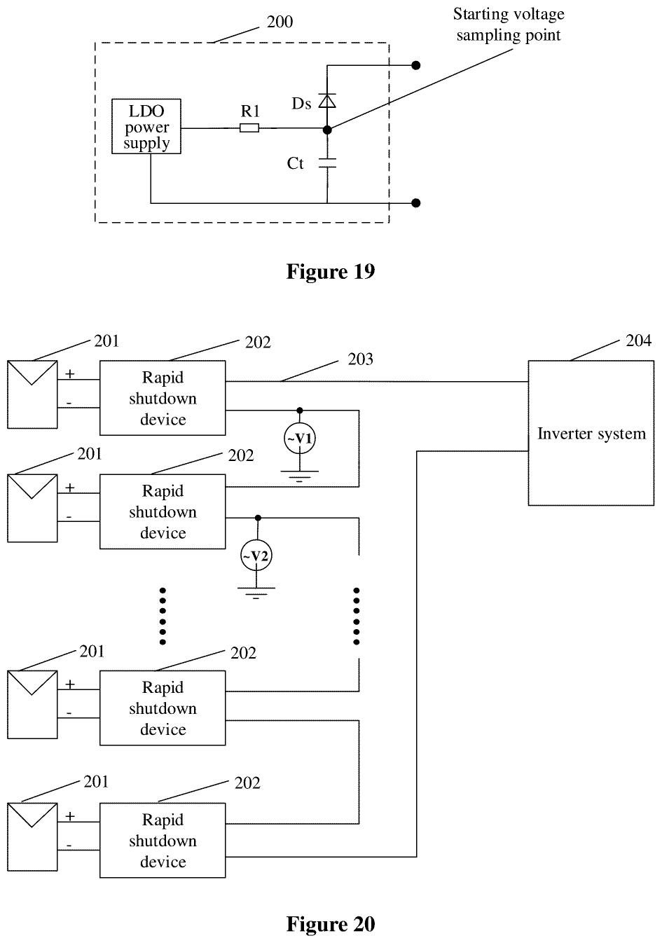

In practice, the low-voltage power supply 105 includes an LDO power supply and a current-limiting resistor R1, as shown in FIG. 19 (drawn based on FIG. 18).

As shown in FIG. 19, a terminal of the LDO power supply is connected to one terminal of the current-limiting resistor R1, and the other terminal of the current-limiting resistor R1 is connected to the anode of the anti-backflow diode Ds and one terminal of the first capacitor Ct. The other terminal of the LDO power supply is connected to the other terminal of the first capacitor Ct.

Alternatively, a terminal of the LDO power supply is connected to one terminal of the current-limiting resistor R1, and the other terminal of the current-limiting resistor R1 is connected to the anode of the anti-backflow diode Ds. One terminal of the first capacitor Ct is connected to the cathode of the anti-backflow diode Ds. Another terminal of the LDO power supply is connected to the other terminal of the first capacitor Ct (not shown in the drawings).

The LDO power supply outputs a direct-current voltage of 1V or another value, depending on the actual situations. All the implementations fall within the protection scope of the present disclosure.

The processor 103 is further configured to determine, based on the starting voltage instead of the output voltage of the rapid shutdown device, whether the change in the voltage across the direct-current bus connected to the rapid shutdown device meets the preset conduction condition. The output terminal of the processor 103 is connected to the control terminal of the switch transistor unit via the driving circuit 101. The processor 103 is configured to, cooperating with the starting voltage module 200, the parameter sampling module, the driving circuit 101 and the switch transistor unit, control the rapid shutdown device to perform the method for starting a rapid shutdown system described in the above embodiments. Specifically, the rapid shutdown system determines based on a detected voltage outputted by itself, whether a change in the voltage across the direct-current bus connected to itself meets a preset conduction condition and switches on in response to its determination that the change in the voltage across the direct-current bus already meets the preset conduction condition.

In the embodiment, the processor 103 controls the rapid shutdown device to be turned on based on the starting voltage instead of the output voltage of the rapid shutdown device, effectively preventing the erroneous determination resulted from that the output voltage of the rapid shutdown device is prone to interference. Therefore, the parameter sampling module preferably samples the starting voltage, and the processor 103 determines based on the starting voltage whether the change in the voltage across the direct-current bus connected to the rapid shutdown device meets the preset conduction condition.

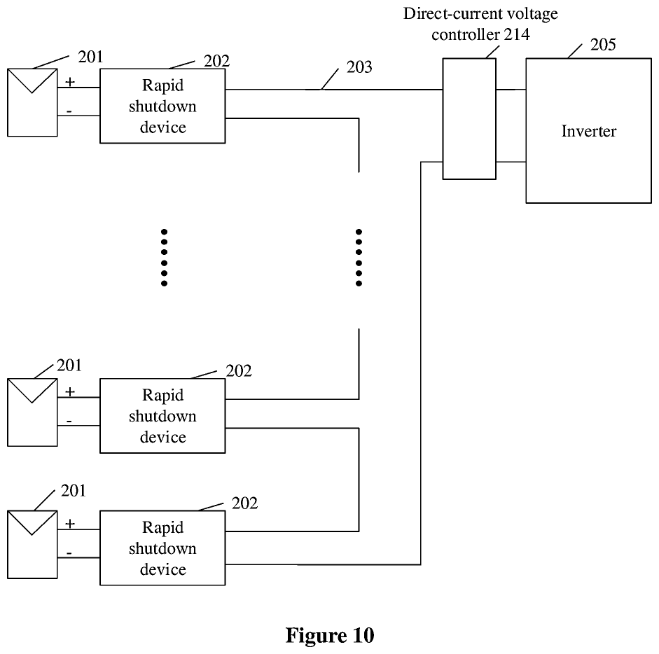

An inverter system is provided according to an embodiment of the present disclosure. As shown in FIG. 10, the inverter system includes a direct-current voltage control circuit and an inverter 205.

The direct-current voltage control circuit is configured to regulate a voltage across a direct-current bus in a rapid shutdown system.

The inverter 205 is configured to, cooperating with the direct-current voltage control circuit, control the inverter system to perform the method for starting the rapid shutdown system described in the above embodiments. Specifically, the inverter 205 is configured to regulate the voltage across the direct-current bus. In practice, before regulating the voltage across the direct-current bus, the inverter system detects the voltage across the direct-current bus and determines whether the detected voltage across the direct-current bus meets the starting condition. The inverter 205 regulates the voltage across the direct-current bus in response to its determination that the voltage across the direct-current bus meets the starting condition. The inverter system detects, for each of direct-current buses in the rapid shutdown system, a voltage across the direct-current bus.

In practice, before regulating the voltage across the direct-current bus, the inverter system determines, for each of direct-current buses in the rapid shutdown system, whether the detected voltage across the direct-current bus meets a preset abnormal condition; sends an alarm and regulates the voltage across the direct-current bus according to the preset abnormal condition, operates directly without regulating the voltage across the direct-current bus, or stops operating, in response its determination that there is at least one direct-current bus whose voltage meets the preset abnormal condition. The inverter system regulates the voltage across the direct-current bus in response to its determination that there is no direct-current bus whose voltage meets the preset abnormal condition.

It should be noted that details about the inverter system may refer to the description of the method for starting the rapid shutdown system according to the forgoing embodiments, and thus are not repeated here.

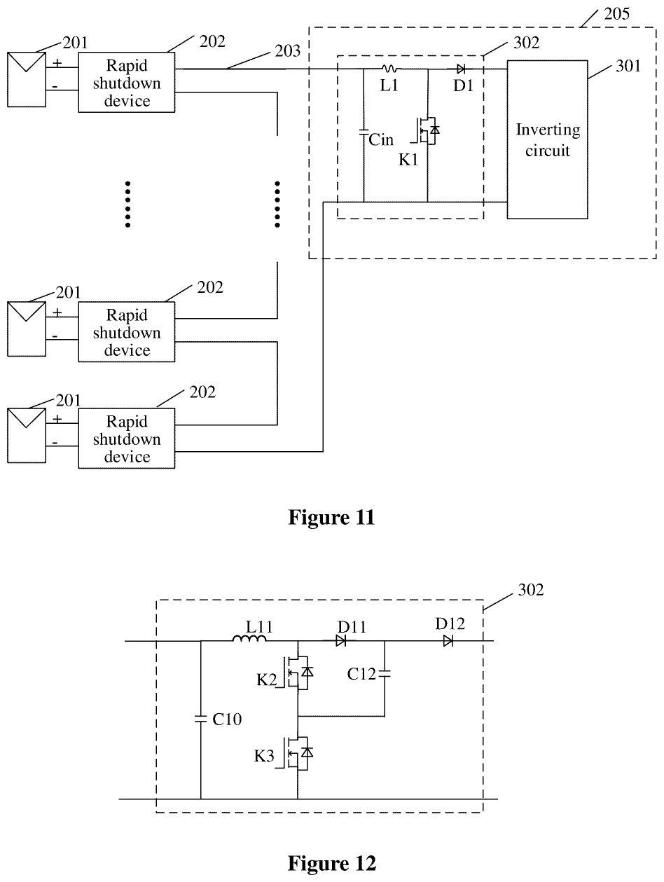

In practice, the direct-current voltage control circuit may be implemented as a direct-current voltage controller 214 independently arranged on the direct-current bus (as shown in FIG. 10), or as a DC/DC circuit 302 arranged in the inverter 205 (as shown in FIG. 11). Hereinafter the two alternatives of the direct-current voltage control circuit are described in detail.

(1) As shown in FIG. 10, the direct-current voltage control circuit is implemented as the direct-current voltage controller 214 arranged on the direct-current bus separately from the. A positive output terminal of the direct-current voltage controller 214 is connected to the inverter 205 positive line of the direct-current bus. A negative output terminal of the direct-current voltage controller 214 is connected to the negative line of the direct-current bus. The inverter 205 includes an inverting circuit. A direct-current side of the inverter circuit serves as a direct-current side of the inverter 205, and an alternating-current side of the inverter circuit serves as an alternating-current side of the inverter 205.

(2) As shown in FIG. 11, the direct-current voltage controller 214 is implemented as the DC/DC circuit 302 arranged in the inverter 205. The inverter 205 further includes an inverter circuit 301. An end of the DC/DC circuit 302 serves as a direct-current side of the inverter 205, another end of the DC/DC circuit 302 is connected to a direct-current side of the inverter circuit 301, and an alternating-current side of inverter circuit 301 serves as the alternating-current side of the inverter 205.

The DC/DC circuit 302 is a boost circuit, e.g., a basic boost circuit (as shown in FIG. 11). Alternatively, the DC/DC circuit 302 is a three-level boost circuit (as shown in FIG. 12). The direct-current bus 203 is alternately short-circuited when all switch transistors in the boost circuit are on and not short-circuited when all the switch transistor transistors in the boost circuit are off, and then the rapid shutdown device detects a small pulse voltage. The rapid shutdown device, when detecting the small pulse voltage, controls a switch transistor unit of itself to be turned on, so that electric power outputted by a photovoltaic module connected to the rapid shutdown device is applied to the direct-current bus.

FIG. 11 illustrates the basic boost circuit as the DC/DC circuit 302. A terminal of an inductor L1 is connected to a terminal of an input capacitor Cin, and a joint of the inductor L1 and the input capacitor Cin in the DC/DC circuit 302 serves as a positive terminal of the inverter 205 at the direct-current side. Another terminal of the inductor L1 is connected to a terminal of a switch transistor K1 and a terminal of a diode D1. A cathode of the diode D1 is connected to a positive terminal of the inverter circuit 301 at the direct-current side. Another terminal of the switch transistor K1 is connected to another terminal of the input capacitor Cin, and a joint of transistor K1 and the input capacitor Cin in the DC/DC circuit 302 serves as a negative terminal of the inverter 205 at the direct-current side and is connected to a negative terminal of the inverting circuit 301 at the direct-current side. The direct-current bus is short-circuited by turning on the switch transistor K1, and the direct-current bus is stopped being short-circuited by turning off the switch transistor K1.

Alternatively, as shown in FIG. 12 (in which only the DC/DC circuit 302 is shown), the DC/DC circuit 302 is a three-level flying capacitor boost circuit. A terminal of an inductor L11 is connected to a terminal of an input capacitor C10, and a joint of the inductor L1 and the input capacitor Cin in the DC/DC circuit 302 serves as a positive terminal of the inverter 205 at the direct-current side. Another terminal of the inductor L11 is connected to a terminal of a switch transistor K2 and a terminal of a diode D11. A cathode of the diode D11 is connected to an anode of a diode D12 and a terminal of a flying capacitor C12. A cathode of the diode D12 is connected to the positive terminal of the inverting circuit 301 at the direct-current side. Another terminal of the switch transistor K2 is connected to a terminal of a switch transistor K3 and another terminal of the flying capacitor C12. Another terminal of the switch transistor K3 is connected to another terminal of the input capacitor C10, and a joint of the switch transistor K3 and the input capacitor C10 in the DC/DC circuit 302 serves as a negative terminal of the inverter 205 at the direct-current side and is connected to a negative terminal of the inverting circuit 301 at the direct-current side. The direct-current bus is short-circuited by turning on the switch transistor K2 and the switch transistor K3, and the direct-current bus is stopped being short-circuited by turning off the switch transistor K2 and the switch transistor K3.

In the embodiments, the direct-current voltage control circuit controls the rapid shutdown device to be turned on or off, and no starting signal sending unit is involved, thereby reducing the cost of the inverter system in terms of hardware. In addition, a larger direct-current combiner box or an additional direct-current combiner box is necessary for the starting signal sending unit, i.e., an additional device arranged on the direct-current bus in the conventional technology, resulting in high construction costs. In the present disclosure, no additional device is arranged on the direct-current bus, thereby reducing the construction costs.

It should be noted that automatic switches are arranged at the positive and negative terminals on the direct-current side of the inverter in the conventional technology, respectively. The rapid shutdown device determines whether the inverter is connected to itself by detecting impedance of the direct-current bus. Large capacitance on the direct-current bus indicates that the inverter is already connected to the rapid shutdown device. The automatic switches arranged on the direct-current side of the inverter results high costs of the inverter. In the present disclosure, no additional control device such as the automatic switch is involved due to the inverter 205 including the DC/DC circuit 302, reducing the costs of the inverter 205.

Reference is made to FIG. 21, which is a schematic diagram illustrating a voltage across the direct-current bus and an output voltage of the rapid shutdown device according to another embodiment of the present disclosure. The inverter 205 alternately converts the voltage across the direct-current bus and does not convert the voltage across the direct-current instead of short-circuiting the direct-current bus and not short-circuiting the direct-current bus as shown in FIG. 3.

It should be noted that the inverter 205 converts the voltage across the direct-current bus by operating the switch transistor r K1 in a PWM mode. When the switch transistor K1 is off, the inverter 205 does not convert the voltage across the direct-current bus.

Correspondingly, the output voltage of the rapid shutdown device changes as shown in FIG. 21. The voltage across the direct-current bus remains at the second voltage when not converted by the inverter 205, and the output voltage of the rapid shutdown device remains at the first voltage. The voltage across the direct-current bus remains at a voltage higher than zero and lower than the second voltage when converted by the inverter 205.

A rapid shutdown system is further provided according to an embodiment of the present disclosure. As shown in FIG. 13, the rapid shutdown system includes at least one shutdown system and at least one inverter system 204. The shutdown system includes a direct-current bus 203, at least N photovoltaic modules 201, and N rapid shutdown devices 202. N is a positive integer.

In the shutdown system, output terminals of the N rapid shutdown devices are cascaded. Input terminals of the N rapid shutdown devices are connected to output terminals of the N photovoltaic modules 201, respectively. A positive terminal obtained after the output terminals of the N rapid shutdown devices 202 are cascaded is connected to a positive terminal of a direct-current interface of the inverter system 204 through a positive line of the direct-current bus 203. A negative terminal obtained after the output terminals of the N rapid shutdown devices 202 are cascaded is connected to a negative terminal of the direct-current interface of the inverter system 204 through a negative line of the direct-current bus. It should be noted that the sign “+” represents a positive terminal and the sign “−” represents a negative terminal.

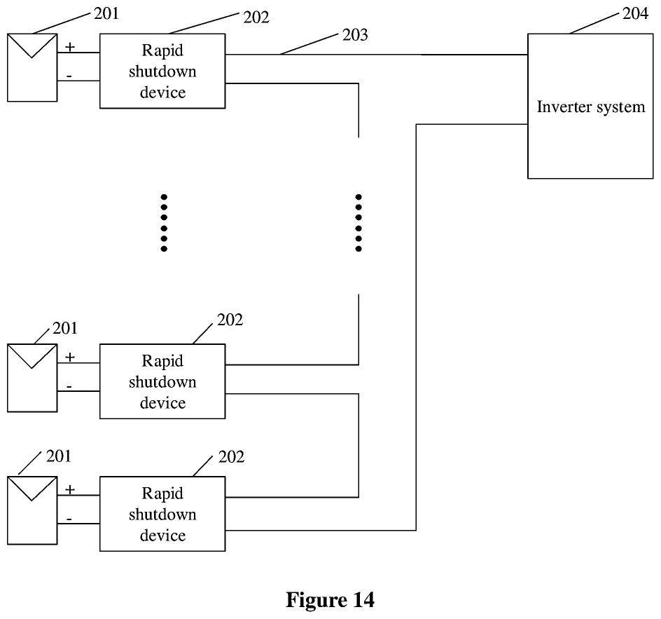

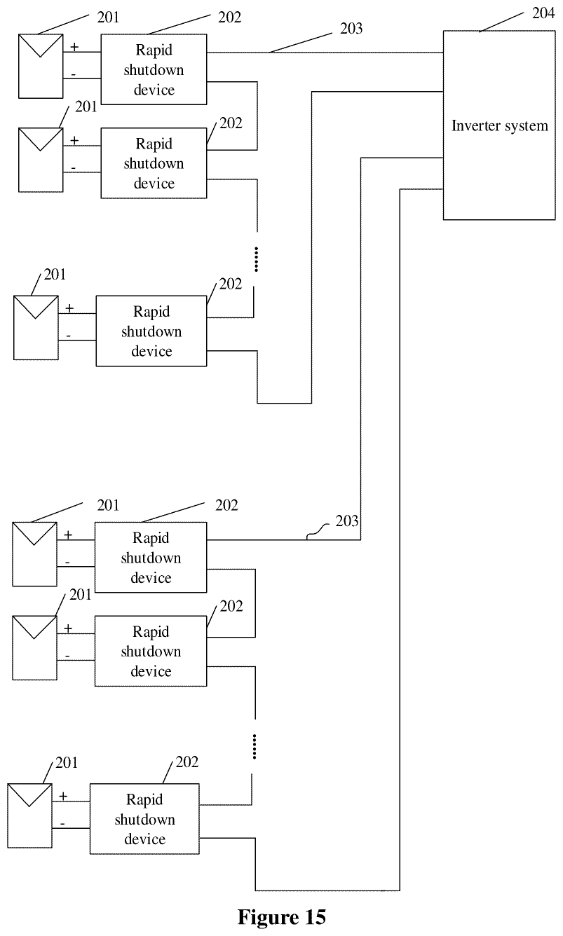

Each of the rapid shutdown devices 202 may be connected to only one photovoltaic module 201 (as shown in FIG. 14), or may be connected to multiple photovoltaic modules 201 (for example, two photovoltaic modules 201 as shown in FIG. 13). The number of the shutdown system may be one (as shown in FIGS. 14 and 13) or more (for example, two shutdown systems as shown in FIG. 15). In the case of one shutdown system, the number of photovoltaic modules 201 connected to one rapid shutdown device 202 may be equal to or different from the number of photovoltaic modules 201 connected to another rapid shutdown device 202, depending on the actual situations. All implementations fall within the protection scope of the present disclosure.

Details about the inverter system 204 may refer to the inverter system 204 in the forgoing embodiments, and thus are not repeated here. Details about the rapid shutdown devices 202 may refer to the rapid shutdown devices 202 in the forgoing embodiments, and thus are not repeated here.

In the embodiment, the rapid shutdown device 202 cooperates with the inverter system 204 in the starting of the rapid shutdown system, which is strongly applicable to industry in which both the rapid shutdown device and the inverter are involved. In addition, the rapid shutdown device 202 and the inverter system 204 in the rapid shutdown system according to the present disclosure leads to low costs in terms of hardware. Accordingly, the rapid shutdown system also leads to costs in terms of hardware.

It should be noted that reference is made to FIG. 20, which is a schematic diagram illustrating a source of an interference voltage at the output end of the rapid shutdown device 202. A first rapid shutdown device 202 and a second rapid shutdown device 202 are taken as examples for description. A common-mode voltage of V1 is generated between a negative output terminal of the first rapid shutdown device 202 and ground, and a common-mode voltage of V2 is generated between a negative output terminal of the second rapid shutdown device 202 and ground. The negative output terminal of the first rapid shutdown device 202 is connected to a positive output terminal of the second rapid shutdown device 202, and thus the second rapid shutdown device 202 outputs a voltage of V1-V2. In a case that V1 and V2 are different in waveforms, an interference voltage is generated at the output end of the second rapid shutdown device 202.

In the embodiment, the rapid shutdown device 202 may be arranged and operate as shown in FIG. 18, thereby preventing the rapid shutdown device 202 from being erroneously turned on due to the interference voltage at its output terminal. In this way, the rapid shutdown system can operate stably and securely.

In the specification, claims and the drawings of the present disclosure, the terms such as “first”, “second” and the like are only used to distinguish similar objects, rather than describe a particular or chronological order. Features described in various embodiments in this specification may be replaced or combined with each other. The same or similar parts among the embodiments may be referred to each other, and each of the embodiments emphasizes the differences from others. Since the system or the embodiments of the system is basically similar to the method therein, the description thereof is relatively simple, and reference may be made to the description of the method for relevant matters. The forgoing system and the embodiments of the system are only schematic. Units described as separated components may be physically separated or not. Components shown as units may be physical units or not, i.e. the components may be located in one place or may be distributed onto multiple network units. Some or all modules thereof may be selected to implement the solutions in the embodiments, depending on actual situations.

It may further be appreciated by those skilled in the art that, the units and algorithmic steps in the examples described according to the embodiments disclosed herein may be implemented in forms of electronic hardware, computer software or the combination of the both. In order to illustrate the interchangeability of the hardware and the software clearly, the components and the steps in the examples are described generally according to functions in the above description. Whether the functions are implemented by hardware or software depends on specific applications and design constraints. For each specific application, those skilled in the art may implement the described functions in carious manners, and none of which is considered to depart from the scope of the present disclosure.

According to the description of the disclosed embodiments, those skilled in the art may implement or use the present disclosure. Various modifications made to these embodiments may be apparent to those skilled in the art, and the general principle defined herein may be implemented in other embodiments without departing from the spirit or scope of the present disclosure. Therefore, the present disclosure is not limited to the embodiments described herein but conforms to a widest scope in accordance with principles and novel features disclosed in the present disclosure.

1. A method for starting a rapid shutdown system, comprising:
regulating, by an inverter system in the rapid shutdown system, a voltage across a direct-current bus in the rapid shutdown system;
determining, by a rapid shutdown device connected to the direct-current bus in the rapid shutdown system based on a detected voltage outputted by the rapid shutdown device, whether a change in the voltage across the direct-current bus meets a preset conduction condition; and
switching the rapid shutdown device on, in response to a determination result that the change in the voltage across the direct-current bus already meets the preset conduction condition, the preset conduction condition is that the voltage across the direct-current bus comprises a small pulse.

2. (canceled)

3. The method for starting a rapid shutdown system according to claim 1, wherein the small pulse is formed by short-circuiting the direct-current bus and stopping short-circuiting the direct-current bus.

4. (canceled)

5. The method for starting a rapid shutdown system according to claim 1, further comprising:
keeping the rapid shutdown device off in response to a determination result that the change in the voltage across the direct-current bus does not meet the preset conduction condition, after the determining, by the rapid shutdown device in the rapid shutdown system connected to the direct-current bus based on a detected voltage outputted by the rapid shutdown device, whether the change in the voltage across the direct-current bus meets the preset conduction condition.

6. The method for starting a rapid shutdown system according to claim 1, further comprising:
before the regulating, by the inverter system in the rapid shutdown system, the voltage across the direct-current bus in the rapid shutdown system,
determining, by the rapid shutdown device, whether a detected state parameter of the rapid shutdown device meets a preset normal condition;
outputting, by the rapid shutdown device, a preset starting voltage to the direct-current bus connected to the rapid shutdown device, in a case that that the state parameter already meets the preset normal condition; and
detecting, by the inverter system, the voltage across the direct-current bus, and determining, by the inverter system, whether the detected voltage across the direct-current bus meets a starting condition, wherein the voltage across the direct-current bus is regulated by the inverter system in a case that the detected voltage across the direct-current bus already meets the starting condition.

7. (canceled)

8. The method for starting a rapid shutdown system according to claim 6, wherein the detecting, by the inverter system, the voltage across the direct-current bus, and determining, by the inverter system, whether the detected voltage across the direct-current bus meets the starting condition comprises:
detecting, by the inverter system, the voltage across the direct-current bus;
determining, by the inverter system based on the detected voltage across the direct-current bus, the number of the rapid shutdown device that has outputted the starting voltage to the direct-current bus;
determining, by the inverter system, whether the number of the rapid shutdown device that has outputted the starting voltage is greater than or equal to a preset number;
determining that the voltage across the direct-current bus already meets the starting condition, in a case that the number of the rapid shutdown device that has outputted the starting voltage is greater than or equal to the preset number; and
determining that the voltage across the direct-current bus does not meet the starting condition in a case that the number of the rapid shutdown device that has outputted the starting voltage is less than the preset number.

9. The method for starting a rapid shutdown system according to claim 1, wherein the regulating, by the inverter system in the rapid shutdown system, the voltage across the direct-current bus in the rapid shutdown system comprises:
regulating, by the inverter system, the voltage across the direct-current bus in a preset manner, so that the voltage across the direct-current bus changes in a preset pattern.

10. The method for starting a rapid shutdown system according to claim 9, wherein the regulating, by the inverter system, the voltage across the direct-current bus in the preset manner comprises:
short-circuiting the direct-current bus throughout a first period of time and stopping short-circuiting the direct-current bus throughout a second period of time alternately.

11. (canceled)

12. The method for starting a rapid shutdown system according to claim 1, further comprising:
before the regulating, by the inverter system in the rapid shutdown system, the voltage across the direct-current bus in the rapid shutdown system,
detecting, by the inverter system for each of direct-current buses in the rapid shutdown system, a voltage across the direct-current bus;
determining, by the inverter system for each of the direct-current buses, whether the voltage across the direct-current bus meets a preset abnormal condition; and
sending an alarm by the inverter system, and regulating by the inverter system the voltage across the direct-current bus according to the preset abnormal condition, directly operating the inverter system without regulating the voltage across the direct-current bus, or stopping operating the inverter system, in a case that there is at least one direct-current bus among the direct-current buses whose voltage already meets the preset abnormal condition, wherein the voltage across the direct-current bus is regulated by the inverter system in a case that voltages respectively across all the direct-current buses do not meet the preset abnormal condition.

13. The method for starting a rapid shutdown system according to claim 12, wherein the regulating by the inverter system the voltage across the direct-current bus according to the preset abnormal condition comprises:
limiting a pulse width to be within a preset range and short-circuiting the direct-current bus throughout the first period of time and stopping short-circuiting the direct-current bus throughout the second period of time, in a case that the voltage across the direct-current bus that already meets the preset abnormal condition is less than a first preset voltage.

14. The method for starting a rapid shutdown system according to claim 13, wherein the directly operating the inverter system without regulating the voltage across the direct-current bus comprises:
keeping the rapid shutdown device connected to the direct-current bus off without short-circuiting the direct-current bus, in a case that the voltage across the direct-current bus that already meets the preset abnormal condition is greater than a second preset voltage, wherein the second preset voltage is greater than or equal to the first preset voltage.

15. The method for starting a rapid shutdown system according to claim 1, further comprising:
determining, by the rapid shutdown device based on a starting voltage of the rapid shutdown device instead of the voltage outputted by the rapid shutdown device, whether the change in the voltage across the direct-current bus meets the preset conduction condition.

16. The method for starting a rapid shutdown system according to claim 9, wherein the regulating, by the inverter system, the voltage across the direct-current bus in a preset manner comprises:
converting the voltage across the direct-current bus throughout the first period of time, and stopping converting the voltage across the direct-current bus throughout the second period of time alternately.

17. The method for starting a rapid shutdown system according to claim 9, wherein the preset pattern is that the voltage across the direct-current bus has a preset value throughout the first period of time and is equal to a corresponding value throughout the second period of time, wherein the preset value is less than the corresponding value.

18. A rapid shutdown device, comprising:
a switch transistor unit;
a starting voltage module;
a driving circuit;
a processor;
a bypass diode; and
a parameter sampling module, wherein
the switch transistor unit is arranged between a negative input terminal and a negative output terminal of the rapid shutdown device or is arranged between a positive input terminal and a positive output terminal of the rapid shutdown device, and is configured to turn on and turn off the rapid shutdown device under control of the processor;
the parameter sampling module is configured to sample a state parameter and an output voltage of the rapid shutdown device and output the sampled state parameter and the sampled output voltage to the processor;
the starting voltage module is configured to output, under the control of the processor, a starting voltage to an output end of the rapid shutdown device, in a case that the rapid shutdown device is off and the state parameter of the rapid shutdown device already meets a preset normal condition;
the bypass diode is configured to provide a path bypass the rapid shutdown device in a case that the rapid shutdown device is off; and
an output terminal of the processor is connected to a control terminal of the switch transistor unit via the driving circuit; and the processor is configured to, cooperating with the starting voltage module, the parameter sampling module, the driving circuit and the switch transistor unit, control the rapid shutdown device to:
determine, based on the output voltage of the rapid shutdown device, whether a change in a voltage across a direct-current bus connected to the rapid shutdown device meets a preset conduction condition; and
switch on in a case that the change in the voltage across the direct-current bus connected to the rapid shutdown device already meets the preset conduction condition.

19. The rapid shutdown device according to claim 18, configured to:
determine whether the state parameter of the rapid shutdown device meets a preset normal condition; and
output a preset starting voltage to the direct-current bus connected to the rapid shutdown device in a rapid shutdown system, in a case that the state parameter already meets the preset normal condition.

20. (canceled)

21. The rapid shutdown device according to claim 19, wherein the parameter sampling module comprises:
an input voltage sampling unit configured to sample an input voltage of the rapid shutdown device; and
an output voltage sampling unit configured to sample the output voltage of the rapid shutdown device.

22. (canceled)

23. The rapid shutdown device according to claim 18, wherein the switch transistor unit comprises at least one switch transistor module, wherein
in a case of one switch transistor module, an input terminal of the switch transistor module serves as an input terminal of the switch transistor unit, an output terminal of the switch transistor module serves as an output terminal of the switch transistor unit, and a control terminal of the switch transistor module serves as a control terminal of the switch transistor unit; and
in a case of two or more switch transistor modules, an input terminal of a branch obtained by connecting all the switch transistor modules in series serves as the input terminal of the switch transistor unit, an output terminal of the branch serves as the output terminal of the switch transistor unit, and control terminals of all the switch transistor modules serve as the control terminal of the switch transistor unit.

24. The rapid shutdown device according to claim 18, wherein
the parameter sampling module is further configured to sample a starting voltage at a starting voltage sampling point in the starting voltage module, and output the sampled starting voltage to the processor; and
the processor is further configured to control the rapid shutdown device to determine, based on a starting voltage of the rapid shutdown device instead of the output voltage of the rapid shutdown device, whether the change in the voltage across the direct-current bus connected to the rapid shutdown device meets the preset conduction condition.

25.-26. (canceled)

27. An inverter system, comprising:
a direct-current voltage control circuit configured to regulate a voltage across a direct-current bus in a rapid shutdown system; and
an inverter configured to cooperate with the direct-current voltage control circuit in the regulating the voltage across the direct-current bus in the rapid shutdown system.

28. The inverter system according to claim 27, wherein the inverter system is further configured to:
detect the voltage across the direct-current bus in the rapid shutdown system, and determine whether the voltage across the direct-current bus meets a starting condition before regulating the voltage across the direct-current bus in the rapid shutdown system, wherein the voltage across the direct-current bus is regulated by the inverter system in a case that the voltage across the direct-current bus already meets the starting condition.

29. The inverter system according to claim 27, wherein the inverter system is further configured to, before regulating the voltage across the direct-current bus in the rapid shutdown system,
detect, for each of direct-current buses in the rapid shutdown system, a voltage across the direct-current bus;
determine, for each of the direct-current buses in the rapid shutdown system, whether the voltage across the direct-current bus meets a preset abnormal condition; and
send an alarm, and regulate the voltage across the direct-current bus according to the preset abnormal condition, directly operate without regulating the voltage across the direct-current bus, or stop operating, in a case that there is at least one direct-current bus among the direct-current buses whose voltage already meets the preset abnormal condition, wherein the voltage across the direct-current bus is regulated by the inverter system in a case that voltages respectively across all the direct-current buses do not meet the preset abnormal condition.

30.-33. (canceled)
